(19) United States
(12) Patent Application Publication
(10) Pub. No.: US 2025/0365181 A1
(43) Pub. Date: Nov. 27, 2025

(54) DEVICE AND METHODS FOR DATA COMMUNICATION

(71) Applicant: Microchip Technology Incorporated, Chandler, AZ (US)

(72) Inventor: Steven Lin, New Taipei City (TW)

(73) Assignee: Microchip Technology Incorporated, Chandler, AZ (US)

(21) Appl. No.: 18/942,876

(22) Filed: Nov. 11, 2024

Related U.S. Application Data
(60) Provisional application No. 63/650,566, filed on May 22, 2024.

(51) Int. Cl. H04L 25/49; H03K 7/08

(52) U.S. Cl. CPC H04L 25/4902; H03K 7/08; H04L 25/4906

(57) ABSTRACT

A communication system may enable communication between a transmitter and receiver in a communication medium with high permittivity and high electrical conductivity. An input data value may be encoded as a duration of time, and a transmit actuator may be driven with a signal based on the encoded duration of time. A receive actuator may receive the signal generated by the receive actuator and may calculate a duration of time in the received signal. The duration of time may be converted into a detected data value, the detected data value to represent the input data value transmitted.

### PRIORITY

This application claims priority to commonly owned U.S. Patent Application No. 63/650,566 filed May 22, 2024, the entire contents of which are hereby incorporated by reference for all purposes.

### FIELD OF THE INVENTION

The present disclosure relates to a system and method for data communication.

### BACKGROUND

In communication systems, electromagnetic wave strength may be attenuated over long distances. As one of various examples, in radio communication over the air, electromagnetic wave strength follows the inverse square law, such that signal strength decreases with the square of the distance from the transmitter. As one of various examples, if the distance from the transmitter is doubled, the signal strength will decrease by a factor of four.

For communication in media such as water or other liquids with high permittivity and high electrical conductivity, wave strength may be even more greatly attenuated and may prevent communication over long distances. Electromagnetic communication with submersible vehicles or between scuba divers may be limited to very short distances.

Additionally, many receiver systems utilize a self-oscillating system, where the transmitted signal may induce an oscillation in the receiver. Due to the high Q-factor and high sensitivity in the receiver, when transmitting in media with high permittivity and high electrical conductivity a self-oscillating system may generate a long and variable duration signal at the receiver, which may make traditional modulation and de-modulation techniques infeasible. Self-oscillating conditions may persist even when the incoming signal is no longer present.

There is a need for systems and methods for long-distance data communication in media with high permittivity and high electrical conductivity.

### SUMMARY

The examples herein enable a system and method for data communication in media with high permittivity and high electrical conductivity.

According to one aspect, a device includes a transmitter comprising a driver, the driver to receive a data input and the driver coupled to a transmit actuator. The device may include a receiver, the receiver comprising a receive actuator to receive a signal generated by the transmit actuator, an amplifier circuit coupled to the receive actuator, a filter circuit coupled to an output of the amplifier circuit, a comparator coupled to an output of the filter circuit; and a decoder coupled to an output of the comparator. The driver may drive one or more data frames to the transmit actuator, the one or more data frames comprising a logic high voltage for a first fixed duration and a subsequent logic low voltage for a variable duration of time based on the data input. The decoder may calculate a detected duration of time between rising edges in a comparator output and to decode the detected duration of time into a detected data value.

According to one aspect, a system includes a microcontroller coupled to a device, the microcontroller to output a data value to the device. The device may include a transmitter and a receiver. The transmitter may include a driver, the driver to receive the data value from the microcontroller as an input data value and the driver coupled to a transmit actuator. The receiver may include a receive actuator to receive a signal from the transmit actuator, an amplifier circuit coupled to the receive actuator, a filter circuit coupled to the output of the amplifier circuit, a comparator coupled to an output of the filter circuit, and a decoder coupled to an output of the comparator. The driver may drive one or more data frames to the transmit actuator, the one or more data frames comprising a logic high voltage for a fixed duration and a subsequent logic low voltage for a variable duration of time based on the input data value. The decoder may calculate a detected duration of time between rising edges and decode the detected duration of time into a detected data value.

According to one aspect, a method includes steps of: converting an input data value into a duration of time, the duration of time based on the input data value, driving an actuator, the actuator to be driven at a logic high voltage for a fixed duration, and the actuator to be driven at a logic low voltage for the duration of time based on the input data value, receiving a signal at a receiver and detecting rising edges in the received signal, and calculating, at the receiver, a detected duration of time between rising edges and converting the detected duration of time between rising edges into a detected data value.

### BRIEF DESCRIPTION OF THE DRAWINGS

FIG. 1 illustrates one of various examples of a transmitter device in a communication system.

FIG. 2 illustrates one of various examples of a receiver device in a communication system.

FIG. 3 illustrates one of various examples of a driver signal waveform in a communication system.

FIG. 4 illustrates one of various examples of a communication system including a transmitter device and a receiver device.

FIG. 5 illustrates one of various examples of signals in a receiver device.

FIG. 6 illustrates a method of communication.

### DETAILED DESCRIPTION

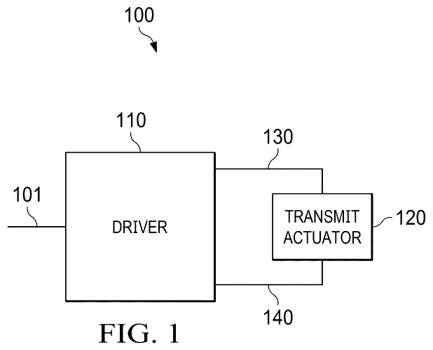

FIG. 1 illustrates one of various examples of a transmitter 100 for data communication. Transmitter 100 may include a driver 110 which may drive a first signal to first output 130 and drive a second signal to second output 140. In one of various examples, the first signal may be the inverse of the second signal.

Data input 101 may be input to driver 110. Data input 101 may be an analog signal provided from a digital-to-analog converter (DAC) or an analog signal from an analog sensor or an analog signal from another analog signal source not specifically mentioned. Data input 101 may be a digital signal provided from an analog-to-digital converter (DAC), a microcontroller, digital signal processor (DSP) or another circuit capable to provide a digital signal.

First output 130 may be coupled to a first node of transmit actuator 120 and second output 140 may be coupled to a second node of transmit actuator 120. Transmit actuator 120 may be a microphone, a speaker, a piezoelectric device, a haptic device, or another type of actuator not specifically mentioned.

Driver 110 may modulate data input 101 to generate first output 130 and second output 140. Driver 110 may generate one or more frames of data based on data input 101 and may drive first output 130 and second output 140 based on data input 101.

In one of various examples, driver 110 may be a pulse-width modulation (PWM) driver, and may generate a PWM signal at first output 130 and a PWM signal at second output 140. Driver 110 may be a microcontroller including a PWM driver. First output 130 and second output 140 may be PWM signals. In one of various examples, second output 140 may be the inverse of first output 130.

In one of various examples, data input 101 may be an audio signal, and driver 110 may generate first output 130 and second output 140 based on data input 101. First output 130 and second output 140 may drive transmit actuator 120 and transmit actuator 120 may produce an audio signal based on data input 101.

The example of FIG. 1 is illustrated with a differential output of driver 110, namely first output 130 and second output 140, but this is not intended to be limiting. In other examples, driver 110 may output a single-ended signal at first output 130, coupled to the first node of transmit actuator 120, and the second node of transmit actuator 120 may be coupled to a common node, including but not limited to a ground node.

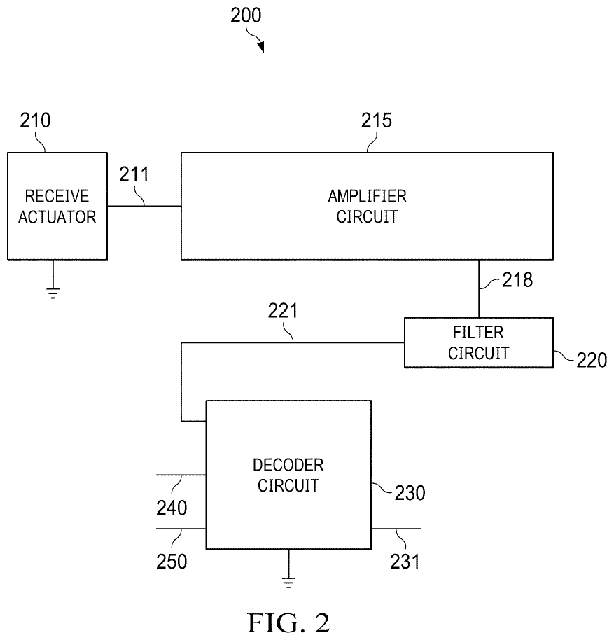

FIG. 2 illustrates one of various examples of a receiver 200 in a communication system. Receiver 200 may include receive actuator 210. Receive actuator 210 may be a microphone, a speaker, a piezoelectric device, a haptic device, or another type of actuator not specifically mentioned.

Receive actuator 210 may be excited by a signal, including but not limited to an acoustic signal, an atmospheric pressure, a vibration signal, or another type of signal not specifically mentioned. Receive actuator 210 may generate a voltage or current at receive actuator output signal 211, receive actuator output signal 211 based on the excitation of receive actuator 210. Receive actuator output signal 211 is illustrated in FIG. 2 as a single-ended signal, but this is not intended to be limiting. Receive actuator output signal 211 may be a differential signal.

Amplifier circuit 215 may amplify receive actuator output signal 211 and may generate amplifier output 218. Amplifier circuit 215 may include one or more operational amplifier circuits, and one or more passive components, including but not limited to capacitors, resistors and inductors. Amplifier circuit 215 may include discrete components, including but not limited to transistors, capacitors, resistors and inductors, or amplifier circuit 215 may be an integrated component including a single semiconductor device.

Filter circuit 220 may filter amplifier output 218. Filter circuit 220 may include one or more diode devices and may perform a rectification of amplifier output 218. Filter circuit 220 may include one or more passive components, including but not limited to resistors and capacitors, and filter circuit 220 may perform a frequency-based filtering of amplifier output 218. Filter circuit 220 may perform a low-pass filter, a high-pass filter, a band-pass filter or a band-stop filter. Filter circuit 220 may apply an all-pass filter function and pass amplifier output 218 to comparator input 221 with no modification of amplifier output 218.

Comparator input 221 may be an output of filter circuit 220. Comparator input 221 may be input to decoder circuit 230. Decoder circuit 230 may receive comparator input 221 and may process comparator input 221 and may decode one or more data bytes based on comparator input 221. In one of various examples, decoder circuit 230 may be a microcontroller including one or more analog inputs and one or more peripherals, the peripherals including one or more comparator circuits. Decoder circuit 230 may include other peripherals not specifically mentioned. Decoder circuit 230 may include clock signal 231.

Decoder circuit 230 may receive comparator input 221 and may couple comparator input 221 to a comparator circuit within decoder circuit 230. The coupling of comparator input 221 to a comparator circuit may be via one or more software instructions or may be via a hardware setting. The comparator circuit within decoder circuit 230 may generate comparator output 240. Comparator output 240 may be a square wave signal based on comparator input 221 and based on a threshold setting.

Decoder circuit 230 may generate edge detection signal 250. Edge detection signal may be based on comparator output 240. As one of various examples, edge detection signal 250 may be based on a logical function of comparator output 240 and a delayed version of comparator output 240. Edge detection signal 250 may be asserted based on a logic high level at comparator output 240 and a logic low level at the delayed version of comparator output 240.

Decoder circuit 230 may compute a detected duration of time between edges of edge detection signal 250 and the detected duration of time may represent a data value. The detected duration of time may be computed based on clock signal 231. The detected duration of time may be an integer number of periods of clock signal 231.

Decoder circuit 230 may decode the detected duration of time between edges of edge detection signal 250 into one or more data values.

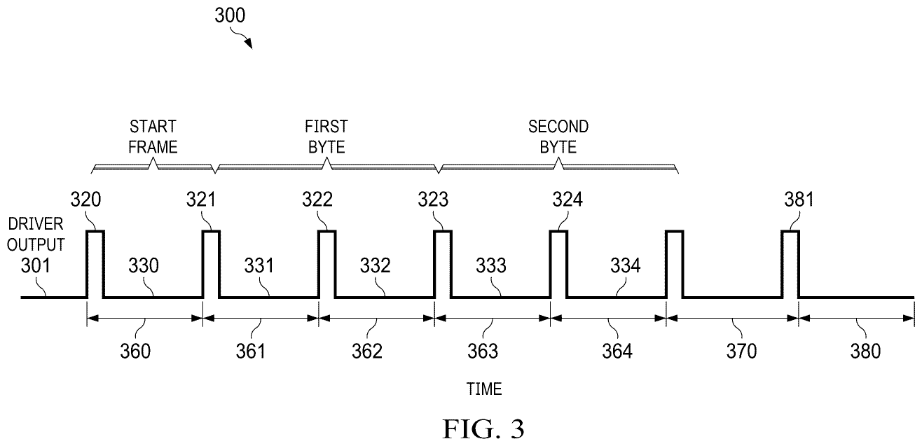

FIG. 3 illustrates one of various examples of a driver output waveform 300 in a communication system. A similar driver output waveform may be used to transmit any number of bytes of data. Driver output waveform 300 may be one of various examples of an output of driver 110 as described and illustrated in reference to FIG. 1.

Driver output 301 may represent one of various examples of a single-ended output of driver 110, as described and illustrated in reference to FIG. 1. Driver output 301 may drive a transmit actuator as described and illustrated in reference to FIG. 1. The transmission may be based on a data input 101 as described and illustrated in reference to FIG. 1.

Time interval 360 may represent a start frame. In one of various examples, at the beginning of the start frame, at time 320, driver output 301 may be a logic high voltage for a first fixed duration. At 330, driver output 301 may be a logic low voltage for a second fixed duration. A receiver may detect the high voltage for a first fixed duration followed by the logic low voltage for a second fixed duration and may detect the start frame. The receiver may be one of various examples of receiver 200 as described and illustrated in reference to FIG. 2. The specific duration of the first fixed duration of a logic high voltage and the second fixed duration of a logic low voltage may be different for different examples of driver output waveform 300. In other examples, at the beginning of the start frame, at time 320, driver output 301 may toggle between a logic high and a logic low voltage for a first fixed duration, and at 330, driver output 301 may stop toggling and may hold at a logic low voltage for a second fixed duration. A receiver may detect the toggling signal for a first fixed duration followed by the logic low voltage for a second fixed duration and may detect the start frame.

As one of various examples, a logic low voltage may be zero volts or may be a ground reference voltage. As one of various examples, a logic high voltage may represent a supply voltage present in a communication system.

As one of various examples, time interval 360 may be termed Ts, and may be set to equal 32 times the period of a reference clock, the period of the reference clock termed Tq. In one of various examples, the reference clock may be clock signal 231 as described and illustrated in reference to FIG. 2.

Time 361 may represent a first data frame. A data input 101 as described and illustrated in reference to FIG. 1 may represent an input data value to be transmitted by driver output waveform 300. In the example illustrated in FIG. 3, time interval 361 may represent transmission of a first four bits of data. At 321, driver output 301 may be a high voltage for a first fixed duration of time, and at 331, driver output 301 may be a logic low voltage for a variable duration of time. The variable duration of 331 may vary based on the input data value to be transmitted. The input data value to be transmitted may be data input 101, as described and illustrated in reference to FIG. 1. In one of various examples, the logic low voltage may be based on multiplying a decimal representation of the first four bits of data by a period of a clock signal. In one of various examples, driver output 301 may be a low voltage for a time based on the following equation: 16*Tq+n*Tq, where Tq represents a unit value of time, which may be, without limitation, a clock period of a reference clock, and where n represents a decimal representation of the input data value to be transmitted. As one of various examples, driver output 301 may be a low voltage for a time of 16*Tq when transmitting an input data value of zero (0x0), and may be a low voltage for a time of 31*Tq when transmitting an input data value of 0xF.

Time interval 362 may represent a second data frame. In the example illustrated in FIG. 3, time interval 362 may represent transmission of a second four bits of data. At 322, driver output 301 may be a high voltage for a first fixed duration of time, and at 332, driver output 301 may be a low voltage for a variable duration of time. The variable duration of 332 may vary based on the input data value to be transmitted. In this manner, a first byte of data may be transmitted during time interval 361 and time interval 362. In one of various examples, the logic low voltage may be based on multiplying a decimal representation of the second four bits of data by a period of a clock signal. In one of various examples, driver output 301 may be a low voltage for a time based on the following equation: 16*Tq+n*Tq, where Tq represents a unit value of time, which may be, without limitation, a clock period of a reference clock, and where n represents a decimal data value to be transmitted. As one of various examples, driver output 301 may be a low voltage for a time of 16*Tq when transmitting an input data value of zero (16*Tq+0*Tq), and may be a low voltage for a time of 31*Tq when transmitting an input data value of 0xF (16*Tq+15*Tq).

Time interval 361 and time interval 362 may in combination represent transmission of one byte of data by driver output waveform 300.

Time interval 363 may represent a third data frame. In the example illustrated in FIG. 3, time interval 363 may represent transmission of a third four bits of data. At 323, driver output 301 may be a high voltage for a first fixed duration of time, and at 333, trace 301 may be a low voltage for a variable duration of time. The variable duration of 333 may vary based on the input data value to be transmitted. In one of various examples, the logic low voltage may be based on multiplying a decimal representation of the third four bits of data by a period of a clock signal. In one of various examples, driver output 301 may be a low voltage for a time based on the following equation: 16*Tq+n*Tq, where Tq represents a unit value of time, which may be, without limitation, a clock period of a reference clock, and where n represents a hexadecimal data value to be transmitted. As one of various examples, driver output 301 may be a low voltage for a time of 16*Tq when transmitting an input data value of zero (0x0), and may be a low voltage for a time of 31*Tq when transmitting an input data value of 0xF.

Time interval 364 may represent a fourth data frame. In the example illustrated in FIG. 3, time interval 364 may represent transmission of a fourth four bits of data. At 324, driver output 301 may be a high voltage for a first fixed duration of time, and at 334, driver output 301 may be a low voltage for a variable duration of time. The variable duration of 334 may vary based on the input data value to be transmitted. In this manner, a second byte of data may be transmitted during time interval 363 and time interval 364. In one of various examples, the logic low voltage may be based on multiplying a decimal representation of the fourth four bits of data by a period of a clock signal. In one of various examples, driver output 301 may be a low voltage for a time based on the following equation: 16*Tq+n*Tq, where Tq represents a unit value of time, which may be, without limitation, a clock period of a reference clock, and where n represents a hexadecimal data value to be transmitted. As one of various examples, driver output 301 may be a low voltage for a time of 16*Tq when transmitting an input data value of zero (0x0), and may be a low voltage for a time of 31*Tq when transmitting an input data value of 0xF.

Time interval 363 and time interval 364 may in combination represent transmission of one byte of data by driver output waveform 300. A byte of data may be transmitted by driving a sequence of a start frame, a first data frame and a second data frame. The first data frame may include driving driver output 301 to a high voltage for a first fixed duration, and driving driver output 301 to a low voltage for a first variable duration, the first variable duration based on the four most significant bits of the data input. The second data frame may include driving driver output 301 to a high voltage for a first fixed duration, and driving driver output 301 to a low voltage for a second variable duration, the second variable duration based on the four least significant bits of the data input.

The example of FIG. 3 illustrates transmission of two bytes of data, but this is not intended to be limiting. Other examples may transmit a different number of bytes of data. Time interval 370 may represent zero or more additional bytes of data transmission.

At 381, driver output 301 may be high for a predetermined time, and end-of-frame duration 380 may signal the end of the frame of data. End-of-frame duration 380 may be dependent on a user's application and may be a different duration in different applications.

The example of FIG. 3 illustrates a single ended solution. In a differential implementation, driver output 301 may drive a first node of a transmit actuator 120, as described and illustrated in reference to FIG. 1, and an inverted version of driver output 301 may drive a second node of a transmit actuator 120, as described and illustrated in reference to FIG. 1.

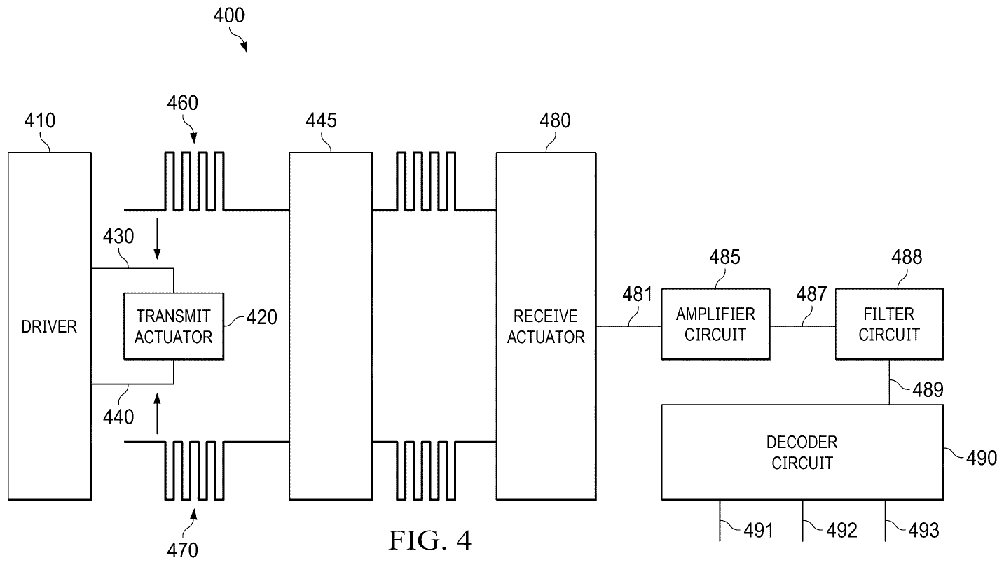

FIG. 4 illustrates one of various examples of a communication system 400 including a transmitter and a receiver.

Communication system 400 may include a driver 410 which may drive a first signal to first output 430 and drive a second signal to second output 440.

Data input 401 may be input to driver 410. Data input 401 may be an analog signal provided from a digital-to-analog converter (DAC) or an analog signal from an analog sensor or an analog signal from another analog signal source not specifically mentioned. Data input 401 may be a digital signal provided from an analog-to-digital converter (DAC), a microcontroller, digital signal processor (DSP) or another circuit capable to provide a digital signal.

First output 430 may be coupled to a first node of transmit actuator 420 and second output 440 may be coupled to a second node of transmit actuator 420. Transmit actuator 420 may be a microphone, a speaker, a piezoelectric device, a haptic device, or another type of actuator not specifically mentioned.

Driver 410 may modulate data input 401 to generate first output 430 and second output 440. In one of various examples, second output 440 may be an inverted version of first output 430. Driver 410 may generate one or more frames of data based on data input 401 and may drive first output 430 and second output 440 based on data input 401.

Driver 410 may generate first output 430 based on data input 401. First waveform 460 may represent a signal at first output 430. First waveform 460 as shown is for illustrative purposes and is not intended to limit the frequency, polarity, voltage levels and timing of first waveform 460. First waveform 460 may be one of various examples of driver output 301 as described and illustrated in FIG. 3. First waveform 460 may be an inverted version of driver output 301 as described and illustrated in FIG. 3.

Driver 410 may generate first output 430 based on data input 401. Second waveform 470 may represent a signal at second output 440. Second waveform 470 as shown is for illustrative purposes and is not intended to limit the frequency, polarity, voltage levels and timing of second waveform 470. Second waveform 470 may be one of various examples of driver output 301 as described and illustrated in FIG. 3. Second waveform 470 may be an inverted version of driver output 301 as described and illustrated in FIG. 3.

In one of various examples, driver 410 may be a pulse-width modulation (PWM) driver, and may generate a positive polarity PWM signal at first output 430 and a negative polarity PWM signal at second output 440. The negative polarity PWM signal may be an inverted version of the positive polarity PWM signal. Driver 410 may be a microcontroller including a PWM driver. First output 430 and second output 440 may be PWM signals.

In one of various examples, data input 401 may be an audio signal, and driver 410 may generate first output 430 and second output 440 based on data input 401. First output 430 and second output 440 may drive transmit actuator 420 and transmit actuator 420 may produce an audio signal based on data input 401.

Driver 410 and transmit actuator 420 may be a transmitter.

The signal produced at transmit actuator 420 may pass through communication medium 445. Communication medium 445 may be air, water, an electrically conductive metal, or another medium not specifically mentioned. The signal produced at transmit actuator 420 may be received at receive actuator 480.

Receive actuator 480 may be a microphone, a speaker, a piezoelectric device, a haptic device, or another type of actuator not specifically mentioned.

The signal received at receive actuator may be, without limitation, an acoustic signal, an atmospheric pressure, a vibration signal, or another type of signal not specifically mentioned. Receive actuator 480 may generate a voltage or current at receive actuator output signal 481, receive actuator output signal 481 based on the excitation of receive actuator 480. Receive actuator output signal 481 is illustrated in FIG. 4 as a single-ended signal, but this is not intended to be limiting. Receive actuator output signal 481 may be a differential signal.

Amplifier circuit 485 may amplify receive actuator output signal 481 and may generate amplifier output 487. Amplifier circuit 485 may include one or more operational amplifier circuits, and one or more passive components, including but not limited to capacitors, resistors and inductors. Amplifier circuit 485 may include discrete components, including but not limited to transistors, capacitors, resistors and inductors, or amplifier circuit 485 may be an integrated component including a single semiconductor device.

Filter circuit 488 may filter the amplifier output 487. Filter circuit 488 may include one or more diode devices and may perform a rectification of amplifier output 487. Filter circuit 488 may include one or more passive components, including but not limited to resistors and capacitors, and filter circuit 488 may perform a frequency-based filtering of amplifier output 487. Filter circuit 488 may perform a low-pass filter, a high-pass filter, a band-pass filter or a band-stop filter. Filter circuit 488 may implement an all-pass function and may pass amplifier output 487 to comparator input 489 with no frequency modification.

Comparator input 489 may be an output of filter circuit 488. Comparator input 489 may be input to decoder circuit 490. Decoder circuit 490 may be a microcontroller including one or more analog inputs and one or more peripherals, the peripherals including one or more comparator circuits. Decoder circuit 490 may include other peripherals not specifically mentioned. Decoder circuit 490 may include clock signal 491.

Decoder circuit 490 may receive comparator input 489 and may couple comparator input 489 to a comparator circuit within decoder circuit 490. The coupling of comparator input 489 to a comparator circuit may be via one or more software instructions or may be via a hardware setting. The comparator circuit within decoder circuit 490 may generate comparator output 492. Comparator output 492 may be a square wave signal based on comparator input 489 and based on a threshold setting.

Decoder circuit 490 may generate edge detection signal 493. Edge detection signal 493 may be based on comparator output 492. As one of various examples, edge detection signal 493 may be based on a logical function of comparator output 492 and a delayed version of comparator output 492. Edge detection signal 493 may be asserted based on a logic high level at comparator output 492 and a logic low level at the delayed version of comparator output 492.

Decoder circuit 490 may compute a detected duration of time between edges of edge detection signal 493 and the detected duration of time may represent a detected data value. The detected duration of time may be computed based on clock signal 491. The detected duration of time may be based on a duration of time between rising edges of the comparator output.

The example of FIG. 4 is illustrated with a differential output of driver 410, namely first output 430 and second output 440, but this is not intended to be limiting. In other examples, driver 410 may output a single-ended signal at first output 430, coupled to the first node of transmit actuator 420, and the second node of transmit actuator 420 may be coupled to a ground node.

The example of FIG. 4 is illustrated with a differential receive actuator 480, but this is not intended to be limiting. In other examples, driver 410 may output a single-ended signal at first output 430, coupled to the first node of transmit actuator 420, and the second node of transmit actuator 420 may be coupled to a ground node.

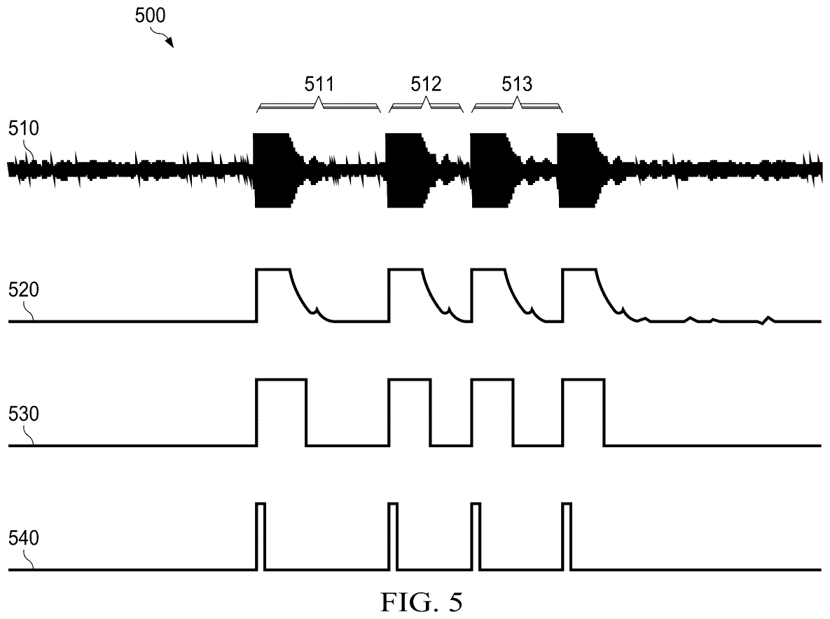

FIG. 5 illustrates one of various examples of signals 500 in a receiver device.

Trace 510 may represent one of various examples of amplifier output 487, as described and illustrated in reference to FIG. 4. Duration 511 may represent a start frame. Trace 510 may transition during a first portion of duration 511, and may cease transitions during a second portion of duration 511. The length of the first portion of duration 511 and the length of the second portion of duration 511 shown in FIG. 5 are for illustrative purposes and are not intended to be limiting.

Duration 512 may represent a first data frame. Duration 513 may represent a second data frame.

Trace 520 may represent one of various examples of comparator input 489 as described and illustrated in reference to FIG. 4. Trace 520 may be a filtered version of trace 510. Trace 520 may be a low-pass filtered version of trace 510, but this is not intended to be limiting.

Trace 530 may represent comparator output 492 as described and illustrated in reference to FIG. 4. Trace 520 may be input to a comparator, and may produce trace 530 based on a threshold setting. The comparator may be part of a decoder circuit, a microcontroller, or may be a dedicated logic circuit.

Trace 540 may be one of various examples of edge detection signal 493 as described and illustrated in reference to FIG. 4. Trace 540 may be generated based on trace 530. In one of various examples, trace 540 may be generated based on a logical function of trace 530 and a delayed version of trace 530. As one of various examples, trace 540 may be asserted when trace 530 is at a logic high level and when a delayed version of trace 530 is at a logic low level.

A receiver may receive trace 540 and may decode the detected duration of time between edges of trace 540 as one or more bytes of data.

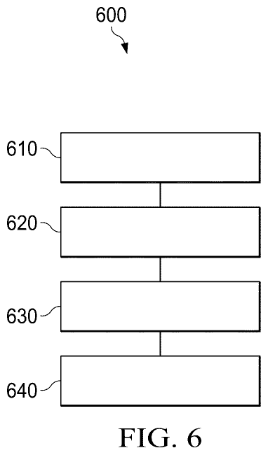

FIG. 6 illustrates a method of communication.

At operation 610, an input data value may be converted into one or more periods of time, the one or more periods of time based on the input data value.

At operation 620, a driver may drive a transmit actuator. In one of various examples the driver may, during a first period, drive the transmit actuator to a high voltage for a first fixed duration, and may, during a second period, drive the actuator to a low voltage for a variable duration, the variable duration based on the one or more periods of time.

At operation 630, a receiver may receive a signal at a receive actuator.

At operation 640, the receiver may calculate one or more periods of time based on the received signal and may decode the one or more periods of time into one or more detected data values. In one of various examples, a decoder circuit may compute a detected duration of time between edges in the received signal, the detected duration of time between edges in the received signal to be decoded into a data value. The detected duration of time may be converted into a detected data value based on dividing the detected duration of time by a period of a clock signal.

1. A device comprising:
a transmitter comprising a driver, the driver to receive a data input and the driver coupled to a transmit actuator;
a receiver comprising:
a receive actuator to receive a signal generated by the transmit actuator;
an amplifier circuit coupled to the receive actuator;
a filter circuit coupled to an output of the amplifier circuit;
a comparator coupled to an output of the filter circuit; and
a decoder coupled to an output of the comparator,
wherein the driver to drive one or more data frames to the transmit actuator, the one or more data frames comprising a logic high voltage for a first fixed duration and a subsequent logic low voltage for a variable duration of time based on the data input, the decoder to calculate a detected duration of time between rising edges in a comparator output and to decode the detected duration of time into a detected data value.

2. The device as claimed in claim 1, the decoder comprising a microcontroller.

3. The device as claimed in claim 1, the driver to drive a start frame, the start frame comprising driving a logic high voltage to the transmit actuator for a first fixed duration and driving a logic low voltage to the transmit actuator for a second fixed duration.

4. The device as claimed in claim 3, the driver to drive one or more data frames comprising driving a logic high voltage to the transmit actuator for a first fixed duration, and driving a logic low voltage to the transmit actuator for a variable duration, the variable duration comprising an integer multiple of a period of a clock signal, the integer multiple based on the data input.

5. The device as claimed in claim 4, the data input comprising a byte of data, the device to transmit the byte of data by transmitting a sequence of: a start frame, a data frame comprising driving a logic high voltage to the transmit actuator for a first fixed duration and driving a logic low voltage to the transmit actuator for a first variable duration, the first variable duration based on the four most significant bits of the byte of data, and a data frame comprising driving a logic high voltage to the transmit actuator for a first fixed duration and driving a logic low voltage to the transmit actuator for a second variable duration, the second variable duration based on the four least significant bits of the byte of data.

6. The device as claimed in claim 5, the first variable duration calculated by multiplying a decimal value of the four most significant bits of the byte of data by a period of a clock signal.

7. The device as claimed in claim 5, the second variable duration calculated by multiplying a decimal value of the four least significant bits of the byte of data by a period of a clock signal.

8. The device as claimed in claim 1, the driver comprising a pulse-width modulation (PWM) circuit.

9. A system comprising:
a microcontroller coupled to a device, the microcontroller to output a data value to the device, the device comprising:
a transmitter comprising a driver, the driver to receive the data value from the microcontroller as an input data value and the driver coupled to a transmit actuator;
a receiver comprising:
a receive actuator to receive a signal from the transmit actuator;
an amplifier circuit coupled to the receive actuator;
a filter circuit coupled to the output of the amplifier circuit;
a comparator coupled to an output of the filter circuit; and
a decoder coupled to an output of the comparator,
wherein the driver to drive one or more data frames to the transmit actuator, the one or more data frames comprising a logic high voltage for a fixed duration and a subsequent logic low voltage for a variable duration of time based on the input data value, the decoder to calculate a detected duration of time between rising edges and decode the detected duration of time into a detected data value.

10. The system as claimed in claim 9, the driver to drive a start frame comprising driving a logic high voltage to the transmit actuator for a first fixed duration and driving a logic low voltage to the transmit actuator for a second fixed duration.

11. The system as claimed in claim 9, the input data value comprising a byte of data, the transmitter to transmit the byte of data by transmitting a sequence by of: a start frame, a data frame comprising driving a logic high voltage to the transmit actuator for a first fixed duration and driving a logic low voltage to the transmit actuator for a first variable duration, the first variable duration based on the four most significant bits of the byte of data, and a data frame comprising driving a logic high voltage to the transmit actuator for a first fixed duration and driving a logic low voltage to the transmit actuator for a second variable duration, the second variable duration based on the four least significant bits of the byte of data.

12. The system as claimed in claim 11, the first variable duration calculated by multiplying a decimal value of the four most significant bits of the byte of data by a period of a clock signal.

13. The system as claimed in claim 11, the second variable duration calculated by multiplying a decimal value of the four least significant bits of the byte of data by a period of a clock signal.

14. The system as claimed in claim 9, the decoder to calculate a detected duration between a first rising edge and second rising edge and to convert the detected duration to a detected data value, the detected data value based on a multiple of a period of a clock signal.

15. A method comprising:
converting an input data value into a duration of time, the duration of time based on the input data value;
driving an actuator, the actuator to be driven at a logic high voltage for a fixed duration, and the actuator to be driven at a logic low voltage for the duration of time based on the input data value;
receiving a signal at a receiver and detecting rising edges in the received signal; and
calculating, at the receiver, a detected duration of time between rising edges and converting the detected duration of time between rising edges into a detected data value.

16. The method as claimed in claim 15, the method comprising transmitting a start frame comprising driving the actuator with a logic high voltage for a first fixed duration of time and driving the actuator with a logic low voltage for a second fixed duration of time.

17. The method as claimed in claim 15, the input data value comprising a byte of data and the converting the input data value into a variable duration of time comprising multiplying the decimal value of the four most significant bits of the input data value by a period of a clock signal.

18. The method as claimed in claim 15, the input data value comprising a byte of data and the converting the input data value into a variable duration of time comprising multiplying the decimal value of the four least significant bits of the input data value by a period of a clock signal.

19. The method as claimed in claim 15, the converting the detected duration of time between rising edges into a detected data value comprising dividing the detected duration of time between rising edges by a period of a clock signal.
